(19) United States
(12) Patent Application Publication
(10) Pub. No.: US 2024/0274459 A1
(43) Pub. Date: Aug. 15, 2024

(54) Method and member for handling an electronic device

(71) Applicant: ALEDIA, ÉCHIROLLES (FR)

(72) Inventors: Christophe LINCHENEAU, Moirans (FR); Nohora CAICEDO, Grenoble (FR)

(21) Appl. No.: 18/564,857

(22) PCT Filed: May 24, 2022
(86) PCT No.: PCT/FR2022/050987

§ 371 Date: Nov. 28, 2023

(30) Foreign Application Priority Data
May 31, 2021 (FR) FR21/05708

(51) Int. Cl. H01L 21/683; H01L 21/67; H01L 25/075

(52) U.S. Cl. CPC H01L 21/6835; H01L 21/67144; H01L 25/0753; H01L 2221/68381

(57) ABSTRACT

The invention relates to a handling member (3) that is able to handle at least one electronic device (1), and to a method for handling such an electronic device (1) from a primary substrate (9). The handling method comprises: —a step (E3) of making the handling member (3) available; —a step (E4) of providing a primary substrate (9) on which the at least one electronic device (1) is disposed; —a step (E6) of temporarily securing the handling member (3) to the at least one electronic device (1); —a step (E9) of separating the handling member (3) and the at least one electronic device (1); —a step (E10) of withdrawing the handling member (3).

### TECHNICAL FIELD

The present disclosure relates to a member for handling at least one electronic device.

The disclosure also relates to a method for handling such an electronic device.

### BACKGROUND

In the field of luminous display screens, the luminous elements constituting the screen should be arranged in a matrix-like fashion in an increasingly accurate manner as the resolution of the screens increases. Each of these light elements comprises at least one light-emitting diode and are organized in the form of a multicolor pixel or in the form of a monochrome subpixel.

It is known to make the light-emitting diodes on an initial support in the form of a silicon or sapphire substrate and to transfer them, onto a reception support different from the initial support and intended to constitute, after this transfer, the luminous display screen.

The transfer of a large number of light-emitting diodes between the initial support and the screen substrate raises numerous technical challenges. Indeed, the selection of a large number of diodes according to a determined spacing at very short distances is complex and sometimes involves the use of technique such as thermocompression which could lead to deterioration of the light-emitting diodes. Moreover, some diodes could be naturally damaged during the general manufacturing process. Hence, the mass transfer sometimes involves the transfer of previously damaged diodes which are deposited over the screen and form black points on the final device.

To solve this problem, it is possible to proceed with a repair or a change of the defective diodes. Although this method allows reducing the number of black points, it involves additional manufacturing steps, which could increase costs and is tedious to implement.

### BRIEF SUMMARY

The present disclosure aims to provide a solution that addresses all or part of the aforementioned problems.

This aim may be achieved thanks to the implementation of a handling member capable of handling at least one electronic device. The handling member comprises a body having a contact surface, said handling member further comprising a plurality of first interaction molecules capable of bonding to the contact surface, said first interaction molecules being intended to interact by reversible chemical interaction with a plurality of second interaction molecules capable of bonding to a functional surface of said at least one device electronic device, said chemical interaction being configured to ensure a temporary securing between said at least one electronic device and the handling member, said chemical interaction could also be broken by applying a chemical and/or physical treatment to molecules selected from the group comprising the plurality of first interaction molecules and the plurality of second interaction molecules, in a manner allowing separating said at least one electronic device and the handling member following the application of said chemical and/or physical treatment.

The above-described arrangements allow providing a handling member configured to displace optoelectronic devices via the first and second interaction molecules. The electronic devices may be separated from the handling member when they are subjected to this chemical and/or physical treatment.

By chemical interaction, it should be understood any type of weak or strong interaction allowing bonding the plurality of first interaction molecules and the plurality of second interaction molecules.

The handling member may also have one or more of the following features, considered separately or in combination.

According to one embodiment, the electronic device is an optoelectronic device.

According to one embodiment, the chemical and/or physical treatment allowing separating said at least one electronic device and the handling member comprises the emission of a light radiation at a first wavelength.

According to one embodiment, the light radiation at the first wavelength is emitted by the handling member, or through the handling member.

According to one embodiment, the plurality of first interaction molecules interacts by covalent bonding with the plurality of second interaction molecules.

According to one embodiment, the plurality of first interaction molecules interacts by hydrogen bonding with the plurality of second interaction molecules.

According to one embodiment, the chemical interaction is a reversible chemical reaction between the plurality of first interaction molecules and the plurality of second interaction molecules.

According to one embodiment, the chemical interaction is a Diels-Alder reaction between the plurality of first interaction molecules and the plurality of second interaction molecules.

According to one embodiment, the chemical interaction is a click chemistry reaction between the plurality of first interaction molecules and the plurality of second interaction molecules.

According to one embodiment, the chemical interaction is a photoaddition reaction, or a Norrish reaction, or a directed photo-substitution reaction, or the like.

According to one embodiment, the chemical interaction is an electrostatic interaction or an interaction between aliphatic species.

According to one embodiment, the electronic device is an optoelectronic device capable of emitting light at a first wavelength, the first interaction molecules being configured to break their chemical interaction with the second interaction molecules when the first interaction molecules are subjected to a light radiation at the first length wave.

In this manner, the electronic device and the handling member may be separated when the first and second interaction molecules are illuminated by a light radiation, for example emitted by the electronic device.

Hence, it should be understood that an optical treatment, and in particular the emission of a light radiation at a first wavelength, is a physical treatment.

According to one embodiment, the electronic device may comprise a light-emitting element comprising at least one light-emitting diode (LED) capable of emitting and/or capturing light, and possibly an electronic control component associated with said at least one light-emitting diode, like for example a transistor. In particular, each diode may comprise a first doped portion intended to be brought into contact with a first electrode, a second doped portion intended to be brought into contact with a second electrode, and an active portion capable of changing state when an external parameter external to the active portion is applied to the active portion, the external parameter being may, for example, consist of the application of a current. In particular, the electronic control component is capable of influencing at least one external parameter associated with the active portion. For example, the electronic control component may be capable of modulating at least one emission parameter relating to the light radiation likely to be emitted by the active portion.

According to one embodiment, the first wavelength is comprised between 400 nm and 800 nm and is in particular substantially equal to 420 nm or substantially equal to 450 nm or substantially equal to 470 nm.

According to one embodiment, the first interaction molecules are configured to interact by chemical interaction with the second interaction molecules when molecules selected from the group comprising the plurality of first interaction molecules and the plurality of second interaction molecules undergo a treatment by a light radiation at a second wavelength different from the first wavelength.

According to one embodiment, the contact surface of the body has contact pads intended to be brought into contact with said at least one electronic device via the first interaction molecules.

According to one embodiment, the contact pads are distributed over the contact surface according to a predetermined spacing corresponding to a spacing between two optoelectronic devices arranged over a primary substrate.

According to one embodiment, the handling member comprises at least one cooperation notch having a shape enabling nesting of the electronic device, or having a shape complementary to the electronic device. In this case, the handling member is configured to be able to nest with the electronic device.

According to one embodiment, the handling member comprises a plurality of cooperation notches separated from one another by the predetermined spacing.

According to one embodiment, the predetermined spacing is defined as the spacing separating two optoelectronic devices on a secondary substrate receiving the optoelectronic devices after handling by the substrate by means of the handling member, in particular a substrate for a luminous display screen. For example, the predetermined spacing may be comprised between 50 μm and 1 mm, and more particularly substantially equal to 100 μm.

According to one embodiment, the first interaction molecules and the second interaction molecules are identical.

According to one embodiment, the first interaction molecules are strictly different from the second interaction molecules.

According to one embodiment, each of at least part of the first interaction molecules comprises a first active site, and at least part of the second interaction molecules comprise a second active site, said first active sites being configured to chemically interact with said second active sites.

According to one embodiment, the first active site and the second active site are identical.

According to another embodiment, the first active site is strictly different from the second active site.

According to one embodiment, the first interaction molecules are configured to interact by chemical interaction with the second interaction molecules when molecules selected from the group comprising the plurality of first interaction molecules and the plurality of second interaction molecules undergo a heat treatment.

According to one embodiment, the first interaction molecules are configured to interact by chemical interaction with the second interaction molecules when molecules selected from the group comprising the plurality of first interaction molecules and the plurality of second interaction molecules undergo a chemical reaction.

The aim of the disclosure may also be achieved by implementing a method for handling at least one electronic device by a primary substrate.

The handling method comprises:
a step of providing a provisional system comprising a primary substrate over which the at least one electronic device is arranged, and a handling member, said at least one electronic device having a functional surface, and said handling member comprising a body having a contact surface, the handling member comprising a plurality of first interaction molecules bonded to the contact surface, said first interaction molecules being in a situation of reversible chemical interaction with a plurality of second interaction molecules which are bonded to the electronic device at the level of the functional surface;
a step of separating the handling member and the at least one electronic device in which a physical and/or chemical treatment is applied to molecules selected from the group comprising the plurality of first molecules interaction and the plurality of second interaction molecules so as to break said chemical interaction between the plurality of first interaction molecules and the plurality of second interaction molecules;
a step of withdrawing the handling member.

The previously-described arrangements allow providing a method for handling optoelectronic devices with respect to a primary substrate. The presence of the plurality of first interaction molecules and of the plurality of second interaction molecules allows attaching the handling member with the electronic device during the phase of providing a provisional system, and enabling the separation of the electronic device and of the handling member during the separation step.

By chemical interaction, it should be understood any type of weak or strong interaction allowing bonding the plurality of first interaction molecules and the plurality of second interaction molecules.

The handling method may also have one or more of the following features, considered separately or in combination.

According to one embodiment, the handling member is separated from the primary substrate during the step of withdrawing the handling member.

According to one embodiment, the handling member is separated from a secondary substrate during the step of withdrawing the handling member.

According to one embodiment, the step of withdrawing the handling member is implemented after the step of separating the handling member and the at least one electronic device.

According to one embodiment, the phase of providing a provisional system comprises:
a step of providing the handling member having the contact surface;
a step of providing the primary substrate over which the at least one electronic device is arranged, which has a functional surface;
a step of temporarily securing the handling member with said at least one electronic device, via the plurality of first interaction molecules and the plurality of second interaction molecules, said first and second interaction molecules interacting with one another by reversible chemical interaction.

According to one embodiment, the chemical and/or physical treatment allowing breaking the chemical interaction between the plurality of first interaction molecules and the plurality of second interaction molecules comprises the emission of one light radiation at a first wavelength.

According to one embodiment, the light radiation at the first wavelength is emitted by the handling member, or through the handling member.

According to one embodiment, said at least one electronic device is an optoelectronic device capable of emitting a light radiation at the first wavelength when it is supplied with electrical energy, the separation step being implemented by supplying the electronic device with electrical energy.

In this manner, the electronic device is capable of emitting a light radiation at the first wavelength in order to carry out said physical and/or chemical treatment necessary for the separation by breaking up the chemical interaction.

Advantageously, the plurality of first interaction molecules and the plurality of second interaction molecules are configured to separate from each other when at least one amongst said plurality is subjected to a light radiation at the first wavelength, for example if an electronic device is an optoelectronic device capable of emitting light. Synergistically, if an electronic device does not emit light, for example if it is damaged, it will not be separated from the handling member. In this manner, the handling method allows selecting a defective electronic device at the surface of a primary substrate which may for example consist of a screen substrate.

According to one embodiment, the supply of the electronic device with electrical energy allows selectively placing the electronic device in an emission mode in which it emits a light radiation at the first wavelength, or in an extinction mode in which it does not emit any light radiation.

According to one embodiment, the handling method comprises a transfer phase implemented after the phase of providing a provisional system, the transfer phase comprising:
a step of detaching said at least one electronic device off the primary substrate, in particular by mechanical tension applied to the body of the handling member; and
a positioning step in which the contact surface of the handling member is positioned opposite a receiving surface of a secondary substrate.

According to one embodiment, the step of detaching said at least one electronic device off the primary substrate is carried out during the step of withdrawing the handling member.

According to one embodiment, during the positioning step, the contact surface of the handling member is positioned opposite a receiving surface of a secondary substrate in a relative position such that the devices electronics are in contact with the receiving surface of the secondary substrate.

According to one embodiment, the transfer phase is implemented before the separation step.

According to one embodiment, the transfer phase is implemented after the separation step.

According to one embodiment, the primary substrate comprises a plurality of electronic devices distributed over an emitting surface of the primary substrate, said emitting surface comprising electronic connections configured to allow powering each electronic device of the plurality of electronic devices individually during a power supply step.

In this manner, it is possible to selectively power the electronic devices so as to carry out the separation step selectively at the level of the electronic devices. In other words, it is possible to individually release each electronic device from contact with the handling member. Thus, the previously-described arrangements allow individually selecting the electronic devices to be handled with the handling member. For example, this may allow withdrawing only some predetermined electronic devices off the surface of the primary substrate (rather than others), like for example the emitting surface.

According to one embodiment, the electrical energy supply step is implemented selectively on at least one electronic device of the plurality of electronic devices.

For example, the electrical energy supply step may be implemented on electronic devices separated in pairs by a predetermined distance, in particular comprised between 50 μm and 1 mm.

According to one embodiment, the handling method comprises a step of functionalizing the contact surface of the handling member implemented before the phase of providing a provisional system, wherein the contact surface is functionalized so as to enable the first interaction molecules to be bonded to the contact surface.

According to one embodiment, the step of functionalizing the contact surface comprises exposing the contact surface to a plasma comprising dioxygen to generate a plurality of hydroxyl bonds.

According to one embodiment, the handling method comprises a step of functionalizing the functional surface of the electronic device implemented before the phase of providing a provisional system, in which the functional surface is functionalized so as to enable the second interaction molecules to be bonded to the functional surface.

According to one embodiment, the step of functionalizing the functional surface comprises exposing the functional surface to a plasma comprising dioxygen to generate a plurality of hydroxyl bonds.

According to one embodiment, the method comprises an activation step, in which at least one amongst the contact surface and the functional surface is subjected to a physical or chemical activation treatment so as to activate reactive chemical groups on the plurality of first interaction molecules and/or on the plurality of second interaction molecules.

According to one embodiment, the activation step comprises a treatment with a light radiation at a second wavelength different from the first wavelength.

According to one embodiment, the temporary securing step is implemented by a reversible chemical reaction between the plurality of first interaction molecules and the plurality of second interaction molecules.

According to one embodiment, the temporary securing step is implemented by a Diels-Alder reaction between the plurality of first interaction molecules and the plurality of second interaction molecules.

According to one embodiment, the temporary securing step is implemented by a click chemistry reaction between the plurality of first interaction molecules and the plurality of second interaction molecules.

According to one embodiment, the temporary securing step is implemented by a photoaddition reaction, or a Norrish reaction, or a directed photo substitution reaction, or the like.

According to one embodiment, the first interaction molecules and/or the second interaction molecules comprise at least one carbon chain.

According to one embodiment, said at least one carbon chain has a distal end at the level of which a distal active site is arranged configured to enable the reversible chemical interaction between the first molecules interaction and the second interaction molecules.

According to one embodiment, said at least one carbon chain has a proximal end at the level of which a proximal active site is arranged configured to enable said at least one carbon chain to be attached to the functional surface or to the contact surface.

Advantageously, the presence of carbon chains in the first interaction molecules and the second interaction molecules favors the interaction of the distal active sites present at the ends of each carbon chain.

### BRIEF DESCRIPTION OF THE DRAWINGS

Other aspects, aims, advantages and features of the disclosure will appear more clearly upon reading the following detailed description of preferred embodiments thereof, given as a non-limiting example, and made with reference to the appended drawings, wherein:

FIG. 1 is a schematic view of some steps of the handling method according to a particular embodiment of the disclosure.

FIG. 2 is a schematic view of some steps of the handling method according to a particular embodiment of the disclosure.

FIG. 3 is a schematic view of the step of temporarily securing the handling method according to a particular embodiment of the disclosure.

FIG. 4 is a schematic view of some steps of the handling method according to a particular embodiment of the disclosure.

FIG. 5 is a schematic view of some steps of the handling method according to a particular embodiment of the disclosure.

FIG. 6 is a schematic view of some steps of the handling method according to a particular embodiment of the disclosure.

FIG. 7 is a schematic view of a particular type of a first interaction molecule or of a second interaction molecule.

### DETAILED DESCRIPTION

In the figures and in the rest of the description, the same references represent identical or similar elements. In addition, the different elements are not represented to scale so as to favor clarity of the figures. Moreover, the different embodiments and variants do not exclude one another and can be combined together.

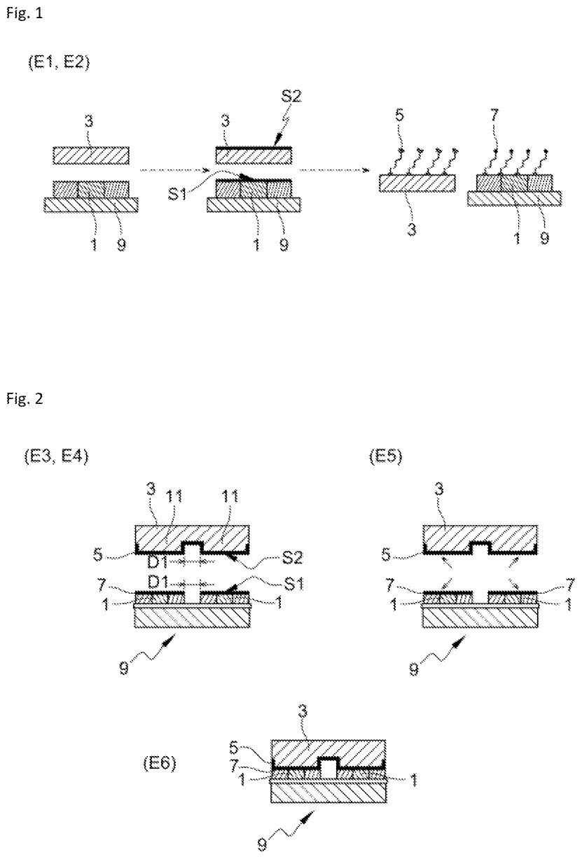

As illustrated in FIGS. 1 to 6, the disclosure first relates to a handling member 3 capable of handling at least one electronic device 1, and also a method for handling such an electronic device 1 by a primary substrate 9. In general, the electronic device 1 is an optoelectronic device intended to be fastened on a receiving face of a secondary substrate 19, like for example a substrate for a luminous display screen, in particular by means of a surface distribution of a plurality of such optoelectronic devices 1 over all or part of the free surface of the receiving face.

According to one embodiment, each optoelectronic device may comprise a light-emitting element comprising at least one light-emitting diode (LED) capable of emitting and/or capturing light, and possibly an electronic control component associated with said at least one light-emitting diode, like for example a transistor. In particular, each diode may comprise a first doped portion intended to be brought into contact with a first electrode, a second doped portion intended to be brought into contact with a second electrode, and an active portion capable of changing state when an external parameter external to the active portion is applied to the active portion, the external parameter could, for example, consist of the application of a current. In particular, the electronic control component is capable of influencing at least one external parameter associated with the active portion. For example, the electronic control component may be capable of modulating at least one emission parameter relating to the light radiation likely to be emitted by the active portion.

Referring to FIG. 1, the handling member 3 comprises a body having a contact surface S2. The handling member further comprises a plurality of first interaction molecules 5 capable of bonding to the contact surface S2. The electronic device 1 has a functional surface S1 on which a plurality of second interaction molecules 7 could be bonded.

As illustrated in FIG. 2, the contact surface S2 of the body may have contact pads 11 intended to be brought in contact with said at least one electronic device 1 via the first interaction molecules 5. The contact pads 11 may be distributed over the contact surface S2 according to a predetermined spacing D1 corresponding to a spacing between two optoelectronic devices 1 arranged over a primary substrate 9.

According to another embodiment which is not represented, the handling member 3 comprises at least one cooperation notch having a shape allowing nesting of the electronic device 1, or having a shape complementary to the electronic device 1. In this case, the handling member 3 is configured to be able to nest with the electronic device 1.

Advantageously, the predetermined spacing D1 may be defined as the spacing separating two electronic devices 1 on a secondary substrate 19 receiving the electronic devices 1 after handling from the substrate primary 9 by means of the handling member 3, in particular a substrate for a luminous display screen. For example, the predetermined spacing D1 may be comprised between 50 μm and 1 mm, and more particularly substantially equal to 100 μm.

The first interaction molecules 5 are intended to interact by reversible chemical interaction with the plurality of second interaction molecules 7. The chemical interaction is configured to ensure temporary securing between said at least one electronic device 1 and the handling member 3. In particular, the chemical interaction may be a reversible chemical reaction between the plurality of first interaction molecules 5 and the plurality of second interaction molecules 7.

For example, the first interaction molecules 5 are configured to interact by chemical interaction with the second interaction molecules 7 when molecules selected from the group comprising the plurality of first molecules interaction 5 and the plurality of second interaction molecules 7 undergo a heat treatment or when they undergo a chemical reaction.

According to a first embodiment, the plurality of first interaction molecules 5 interact by covalent bonding with the plurality of second interaction molecules 7. According to a second embodiment, the plurality of first interaction molecules 5 interact by hydrogen bonding with the plurality of second interaction molecules 7. According to a third embodiment, the chemical interaction is a Diels-Alder reaction between the plurality of first interaction molecules 5 and the plurality of second interaction molecules 7. According to fourth embodiment, the chemical interaction is a click chemistry reaction between the plurality of first interaction molecules 5 and the plurality of second interaction molecules 7. According to a fifth embodiment, the chemical interaction is a photoaddition reaction, or a Norrish reaction, or a directed photo substitution reaction, or the like. According to a sixth embodiment, the chemical interaction is an electrostatic interaction or an interaction between aliphatic species.

According to one embodiment, the first interaction molecules 5 and the second interaction molecules 7 are identical. Alternatively, the first interaction molecules 5 are strictly different from the second interaction molecules 7.

According to one embodiment, each of at least part of the first interaction molecules 5 comprises a first active site, and at least part of the second interaction molecules 7 comprise a second active site, said first active sites being configured to chemically interact with said second active sites.

According to one embodiment, the first active site and the second active site are identical.

According to another embodiment, the first active site is strictly different from the second active site.

Moreover, the chemical interaction joining the first interaction molecules 5 with said second interaction molecules 7 could be broken by application of a chemical and/or physical treatment. The physical and/or chemical treatment is applied to molecules selected from the group comprising the plurality of first interaction molecules 5 and the plurality of second interaction molecules 7, in a manner allowing separating said at least one electronic device 1 and the handling member 3 following the application of said chemical and/or physical treatment. According to one embodiment, the chemical and/or physical treatment allowing separating said at least one electronic device 1 and the handling member 3 comprises the emission of a light radiation at a first wavelength. For example, the light radiation at the first wavelength may be emitted by the handling member 3, or through the handling member 3.

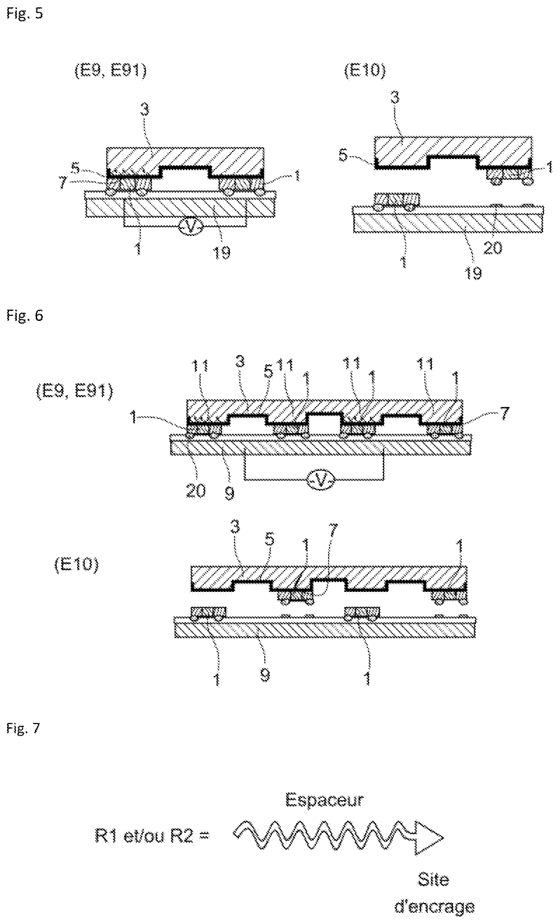

According to a non-limiting variant shown in FIGS. 5 and 6, the electronic device 1 is an optoelectronic device capable of emitting light at the first wavelength. In particular, the first wavelength may be comprised between 400 nm and 800 nm and be in particular substantially equal to 420 nm or substantially equal to 450 nm or substantially equal to 470 nm.

In this case, the first interaction molecules 5 may be configured to break their chemical interaction with the second interaction molecules 7 of the electronic device 1 when the first interaction molecules 5 are subjected to a light radiation at the first wavelength. In this manner, the electronic device 1 and the handling member 3 can be separated when the first and second interaction molecules 5, 7 are illuminated by a light radiation, for example emitted by the electronic device 1.

Advantageously, the first interaction molecules 5 may be configured to interact by chemical interaction with the second interaction molecules 7 when molecules selected from the group comprising the plurality of first interaction molecules 5 and the plurality of second interaction molecules 7 undergo a treatment by a light radiation at a second wavelength different from the first wavelength.

In this manner, the first interaction molecules 5 may be temporarily secured to the second interaction molecules 7 when they undergo a treatment by a light radiation at the second wavelength and separating off the second interaction molecules 7 when they undergo a treatment by a light radiation at the first wavelength. In other words, the handling member 3 and the electronic device 1 may be reversibly attached and detached according to their exposure to the first wavelength or to the second wavelength.

The previously-described arrangements allow providing a handling member 3 configured to displace optoelectronic devices 1 via the first and second interaction molecules 5, 7. The optoelectronic devices 1 may be separated from the handling member 3 when they are subjected to a chemical and/or physical treatment. This may enable a selection of the optoelectronic devices transferred by the handling member or the optoelectronic devices that would be defective.

As indicated before, the disclosure also relates to a method for handling at least one electronic device 1 by a primary substrate 9. In particular, the electronic device 1 may be an optoelectronic device capable of emitting a light radiation at a first wavelength when it is supplied with electrical energy. FIGS. 1 and 2 illustrate some steps of a particular and non-limiting embodiment of the handling method. The handling method comprises a phase of providing a provisional system comprising a handling member 3, and a primary substrate 9 over which the at least one electronic device 1 is arranged. Said at least one electronic device 1 has a functional surface S1, and said handling member 3 comprises a body having a contact surface S2. The handling member comprises, at the level of the contact surface S2, a plurality of first interaction molecules 5 in a situation of reversible chemical interaction with a plurality of second interaction molecules 7 which are bonded to the electronic device 1 at the level of the functional surface S1. According to one embodiment, the phase of providing a provisional system comprises a step E3 of providing a handling member 3, for example of one of the types described before, having the contact surface S2. This contact surface S2 may comprise the plurality of first interaction molecules 5. In particular, FIG. 1 shows a step E1 of functionalizing the contact surface S2 of the handling member 3 implemented before a step E3 of placing the handling member 3. During this step E1, the contact surface S2 is functionalized so as to enable the first interaction molecules 5 to be bonded to the contact surface S2. For example, the step E1 of functionalizing the contact surface S2 may comprise exposing the contact surface S2 to a plasma comprising dioxygen for generating a plurality of hydroxyl groups. According to another variant, step E1 of functionalizing the contact surface S2 comprises functionalization by hooking functions of the amine or silane type, or the like.

Moreover, the phase of providing a provisional system may comprise a step E4 of providing the primary substrate 9 over which the at least one electronic device 1 is arranged, which has the functional surface S1 on which the plurality of second interaction molecules 7 can be bonded. FIG. 1 also shows a step E2 of functionalizing the functional surface S1 of the electronic device 1 implemented before the step E4 of providing the primary substrate 9. During this step E2, the plurality of second interaction molecules 7 is arranged over the functional surface S1. For example, step E2 of functionalizing the functional surface S1 may comprise exposing the functional surface S1 to a plasma comprising dioxygen to generate a plurality of hydroxyl groups. Alternatively, step E2 of functionalizing the functional surface S1 may comprise functionalization by hooking functions of the amine or silane type, or the like.

The handling method may also comprise an activation step E5, in which at least one amongst the contact surface S2 and the functional surface S1 is subjected to a physical or chemical activation treatment so as to activate reactive chemical groups on the plurality of first interaction molecules 5 and/or on the plurality of second interaction molecules 7. For example, the activation step E5 may comprise a treatment with a light radiation at a second wavelength different from the first wavelength.

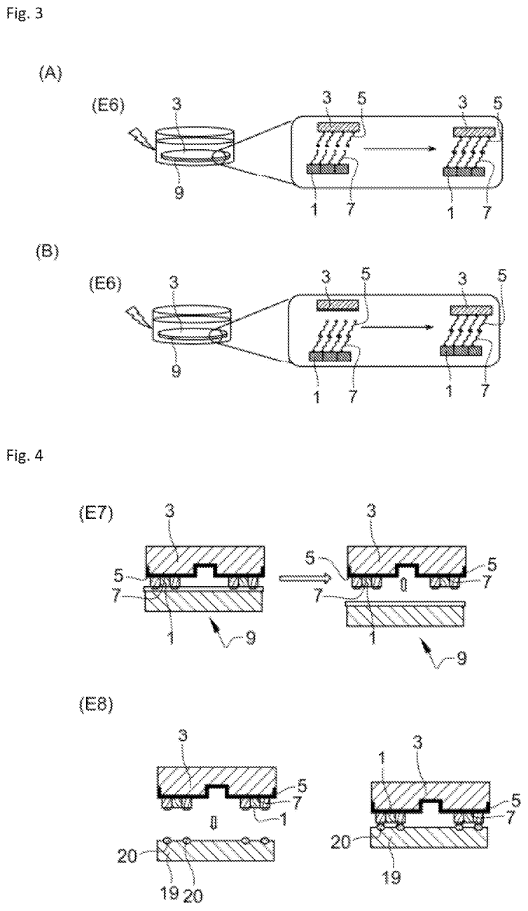

Referring to FIG. 3, the phase of providing a provisional system may comprise a step E6 of temporarily securing the handling member 3 with said at least one electronic device 1, via the plurality of first interaction molecules 5 and the plurality of second interaction molecules 7, said first and second interaction molecules 5, 7 interacting with one another by reversible chemical interaction. In other words, the temporary securing step E6 can be implemented by a reversible chemical reaction between the plurality of first interaction molecules 5 and the plurality of second interaction molecules 7. As illustrated in FIG. 3A, the first interaction molecules 5 can be bonded to the contact surface S2 of the handling member 3, and the second interaction molecules 7 can be bonded to the functional surface S1 of the electronic device 1. In this case, the temporary securing step E6 is implemented by interacting the first and second interaction molecules 5, 7 with one another, by reversible chemical interaction.

Alternatively, and as represented in FIG. 3B, the first and second interaction molecules 5, 7 may be in a situation of reversible chemical interaction with one another, and the second interaction molecules 7 may be bonded to the functional surface S1 of the electronic device 1. In this case, the temporary securing step E6 is implemented by bonding the first interaction molecules 5 at the level of the contact surface S2 of the handling member 3.

Finally, according to a third embodiment which is not represented, the first and second interaction molecules 5, 7 may be in a situation of reversible chemical interaction with one another, and the first interaction molecules 5 may be bonded to the contact surface S2 of the handling member 3. In this case, the temporary securing step E6 is implemented by bonding the second interaction molecules 7 at the level of the functional surface S1 of the electronic device.

After the step E6 of temporarily securing the handling member 3 with the electronic device 1, the handling method may comprise a transfer phase illustrated in FIG. 4.

This transfer phase comprises a step E7 of detaching said at least one electronic device 1 off the primary substrate 9, in particular by mechanical tension applied to the body of the handling member 3, and a positioning step E8 in which the contact surface S2 of the handling member 3 is positioned opposite a receiving surface of a secondary substrate 19, for example in a relative position such that the optoelectronic devices 1 are in contact with the receiving surface of the secondary substrate 19.

As illustrated in FIGS. 5 and 6, the handling method may further comprise a step E9 of separating the handling member 3 and the at least one electronic device 1, implemented before or after the transfer phase, in which a physical and/or chemical treatment is applied to molecules selected from the group comprising the plurality of first interaction molecules 5 and the plurality of second interaction molecules 7. This physical and/or chemical treatment is applied so as to break said chemical interaction between the plurality of first interaction molecules 5 and the plurality of second interaction molecules 7. For example, the chemical and/or physical treatment allowing breaking the chemical interaction between the plurality of first interaction molecules 5 and the plurality of second interaction molecules 7 comprises the emission of a light radiation at a first wavelength. According to a first variant, the light radiation at the first wavelength is emitted by the handling member 3, or through the handling member 3.

According to another variant in which the electronic device 1 is an optoelectronic device capable of emitting a light radiation at a first wavelength when it is supplied with electrical energy, the separation step E9 may be implemented when the electronic device 1 is supplied with electrical energy. In this manner, the electronic device 1 is capable of emitting a light radiation at the first wavelength in order to carry out said physical and/or chemical treatment necessary for the separation by breaking up the chemical interaction. Hence, it should be understood that, according to this embodiment, the plurality of first interaction molecules 5 and the plurality of second interaction molecules 7 are configured to separate when at least one amongst said plurality is subjected to a light radiation at the first wavelength, that is to say in particular when the electronic device 1 emits light. Synergistically, if an optoelectronic device does not emit light, for example if it is damaged, it will not be separated from the handling member 3. In this manner, the handling method allows selecting a defective optoelectronic device at the surface of a primary substrate 9 which may for example be a screen substrate.

According to the embodiment shown in FIGS. 5 and 6, the supply of the optoelectronic device 1 with electrical energy allows selectively setting the optoelectronic device 1 in an emission mode in which it emits a light radiation at the first wavelength, or in an extinction mode in which it does not emit the light radiation at the first wavelength.

FIGS. 5 and 6 show embodiments wherein the primary substrate 9, or the secondary substrate 19 comprise a plurality of electronic devices 1 distributed over an emitting surface of the primary substrate 9 or of the secondary substrate 19. In particular, the emitting surface comprises electronic connections 20 configured to allow powering each electronic device 1 of the plurality of electronic devices 1 individually during a power supply step E91. Hence, the step E91 of supplying electrical energy may be implemented selectively on at least one electronic device 1 of the plurality of electronic devices 1. For example, the electrical energy supply step E91 may be implemented on electronic devices 1 separated in pairs by a predetermined distance, in particular comprised between 50 μm and 1 mm.

In this manner, it is possible to selectively power the electronic devices 1 so as to carry out the separation step E9 selectively at the level of the electronic devices 1. In other words, it is possible to individually release each electronic device 1 from contact with the handling member 3. Thus, the previously-described arrangements allow individually selecting the electronic devices 1 to be handled with the handling member 3. For example, this may allow withdrawing only some predetermined electronic devices 1 off the surface of the primary substrate 9 or off the secondary substrate 19 (and not others), like for example the emitting surface.

Finally, the handling method comprises a step E10 of withdrawing the handling member 3, for example, during the withdrawal step E10, the handling member 3 is separated from the primary substrate 9. Alternatively, the handling member 3 may be separated from a secondary substrate 19 during the step E10 of withdrawing the handling member 3.

According to one embodiment, the step E10 of withdrawing the handling member 3 is implemented after step E9 of separating the handling member 3 and the at least one electronic device 1.

According to another embodiment, the step E10 of withdrawing the handling member 3 is implemented before the step E9 of separating the handling member 3 and the at least one electronic device 1. For example, step E10 of withdrawing the handling member 3 is carried out during the step E7 of detaching said at least one electronic device 1 off the primary substrate 9.

The previously-described arrangements allow providing a method for handling optoelectronic devices 1 with respect to a primary substrate 9. The presence of the plurality of first interaction molecules 5 and of the plurality of second interaction molecules 7 allows attaching the handling member 3 with the electronic device 1 during the temporary securing step E6, and also enabling the separation of the electronic device 1 and the handling member 3 during the separation step E9.

Particular embodiments are described hereinafter allowing implementing the aforementioned general principles.

According to a first non-limiting variant, the temporary securing step E6 is implemented by a Diels-Alder reaction between the plurality of first interaction molecules 5 and the plurality of second interaction molecules 7. By Diels-Alder reaction, it should be understood a chemical reaction in which an alkene is added to a conjugated diene to form a cyclohexene derivative. As a first example, the Diels-Alder reaction may be carried out by reacting a compound of formula C1, with a compound of formula C2, where R, R1 and R2 represent chemical groups which are different from each other or not.

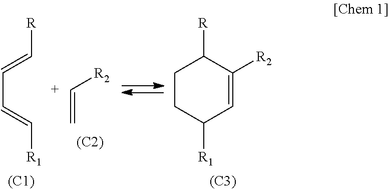

For example, the groups R, R1, and R2 presented herein and in the rest of the description may correspond to groups having hydrophilic functions (like alcoholate chains, ethylene glycols, acrylates, etc.) allowing facilitating the implementation of the method in aqueous solvents. The groups R, R1, and R2 may also correspond to apolar groups (conjugated alkyl or alkene chains), allowing organizing the reagents before a possible optical treatment. Finally, the groups R, R1, and R2 may comprise carbon or oxygenated chains (alkyls, alkenes or ethylene glycols) having a carbon chain length greater than three carbon atoms, and for example less than 20 carbon atoms. For example, these carbon or oxygenated chains may comprise small oligomers (having from 3 to 10 monomers), or peptide chains. Advantageously, these carbon or oxygenated chains allow conferring a greater flexibility on the first interaction molecules 5 or on the second interaction molecules 7, as illustrated in FIG. 7.

In other words, the first interaction molecules 5 and/or the second interaction molecules 7 may comprise at least one carbon chain. Said at least one carbon chain may have a distal end at the level of which a distal active site is arranged configured to enable the reversible chemical interaction between the first interaction molecules 5 and the second interaction molecules 7. Moreover, said at least one carbon chain may have a proximal end at the level of which a proximal active site is arranged configured to allow bonding said at least one carbon chain to the functional surface S1 or to the contact surface S2.

In the above-described case, the temporary securing step E6 is carried out by heat treatment at a first temperature so as to form a compound of formula C3, and the separation step E9 is carried out by heat treatment at a second temperature different from the first temperature.

According to a second example, the Diels-Alder reaction may be carried out by reacting a compound of formula C4, with a compound of formula C5, where R1 and R2 represent chemical groups which are different from each other or not.

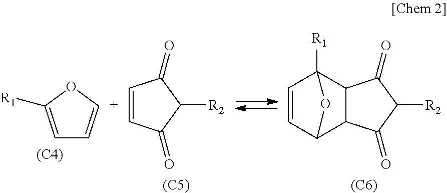

In this case, the temporary securing step E6 may be carried out by heat treatment at a temperature comprised between 25° C. and 120° C. so as to form a compound of formula C6, and the separation step E9 is carried out by heat treatment at a temperature strictly higher than 120° C.

According to a second non-limiting variant, the temporary securing step E6 is implemented by a click chemistry reaction between the plurality of first interaction molecules 5 and the plurality of second interaction molecules 7. As a third example, the click chemistry reaction may be carried out by the reaction of a compound of formula C7, with a compound of formula C8, where R1 and R2 represent chemical groups which are different from each other or not.

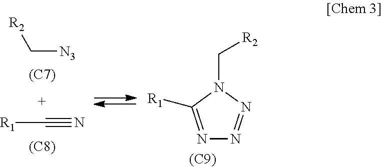

In this example, the temporary securing step E6 is carried out by catalytic reaction in the presence of copper or of a copper organometallic complex, so as to form a cleavable group of formula C9, and the separation step E9 is carried out by a light radiation at a first wavelength. Advantageously, the first wavelength may be selected according to the chemical groups present in the first interaction molecules 5 or in the second interaction molecules 7.

In particular, the first wavelength may be substantially equal to 302 nm when the cleavable group C9 corresponds to the following formula:

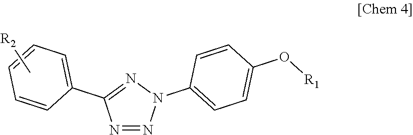

Alternatively, the first wavelength may be substantially equal to 365 nm when the cleavable group C9 corresponds to the following formula:

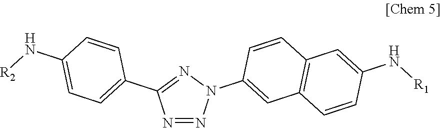

Alternatively, the first wavelength may be substantially equal to 405 nm when the cleavable group C9 corresponds to the following formula:

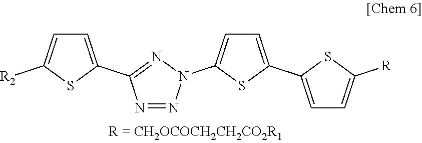

Alternatively, the first wavelength may be substantially equal to 700 nm when the cleavable group C9 corresponds to the following formula:

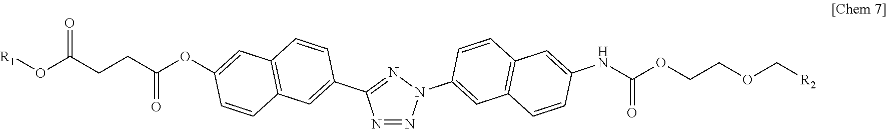

As a fourth example, the click chemistry reaction may be implemented by reacting a compound of formula C10, with a compound of formula C11, where R1 and R2 represent chemical groups that are different from each other or not.

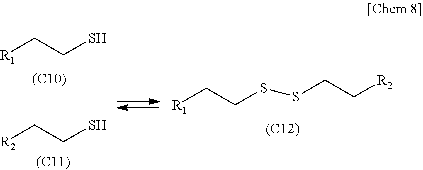

In this example, the temporary securing step E6 is carried out by chemical reaction, so as to form a compound of formula C12, and the separation step E9 is carried out by a light radiation at a first wavelength, for example comprised between 300 nm and 450 nm.

1. A handling member able to handle at least one electronic device, said handling member comprising a body having a contact surface, said handling member further comprising a plurality of first interaction molecules capable of being bonded to the contact surface, said first interaction molecules being intended to interact by reversible chemical interaction with a plurality of second interaction molecules capable of being bonded to a functional surface of said at least one electronic device, said chemical interaction being configured to ensure a temporary securing between said at least one electronic device and the handling member, said chemical interaction could be broken by applying a chemical and/or physical treatment to molecules selected from the group comprising the plurality of first interaction molecules and the plurality of second interaction molecules, in a manner allowing separating said at least one electronic device and the handling member following the application of said chemical and/or physical treatment.

2. The handling member according to claim 1, wherein the chemical and/or physical treatment allowing separating said at least one electronic device and the handling member comprises the emission of a light radiation at a first wavelength.

3. The handling member according to claim 2, wherein the light radiation at the first wavelength is emitted by the handling member, or through the handling member.

4. The handling member according to claim 2, wherein the first interaction molecules are configured to interact by chemical interaction with the second interaction molecules when molecules selected from the group including the plurality of first interaction molecules and the plurality of second interaction molecules undergo a treatment by a light radiation at a second wavelength different from the first wavelength.

5. The handling member according to claim 1, wherein the electronic device is an optoelectronic device capable of emitting light at the first wavelength, the first interaction molecules being configured to break their chemical interaction with the second interaction molecules when the first interaction molecules are subjected to a light radiation at the first wavelength.

6. The handling member of claim 1, wherein the first wavelength is comprised between 400 nm and 800 nm and is in particular substantially equal to 420 nm, or substantially equal to 450 nm, or substantially equal to 470 nm.

7. The handling member according to claim 1, wherein the contact surface of the body has contact pads intended to be brought into contact with said at least one electronic device via the first interaction molecules.

8. The handling member according to claim 7, wherein the contact pads are distributed over the contact surface according to a predetermined spacing corresponding to a spacing between two optoelectronic devices arranged over a primary substrate.

9. The handling member according claim 1, wherein the first interaction molecules are configured to interact by chemical interaction with the second interaction molecules when molecules selected from the group including the plurality of first interaction molecules and the plurality of second interaction molecules undergo a heat treatment.

10. The handling member according to claim 1, wherein the first interaction molecules are configured to interact by chemical interaction with the second interaction molecules when molecules selected from the group including the plurality of first interaction molecules and the plurality of second interaction molecules undergo a chemical reaction.

11. A method for handling at least one electronic device by a primary substrate the handling method comprising:
a phase of providing a provisional system comprising a primary substrate over which the at least one electronic device is arranged, and a handling member, said at least one electronic device having a functional surface, and said handling member comprising a body having a contact surface, the handling member comprising a plurality of first interaction molecules bonded to the contact surface, said first interaction molecules being in a reversible chemical interaction situation with a plurality of second interaction molecules which are bonded to the electronic device at the level of the functional surface;
a step of separating the handling member and the at least one electronic device in which a physical and/or chemical treatment is applied to molecules selected from the group comprising the plurality of first interaction molecules and the plurality of second interaction molecules so as to break said chemical interaction between the plurality of first interaction molecules and the plurality of second molecules interaction;
a step (E10) of withdrawing the handling member.

12. The handling method according to claim 11, wherein the step of providing a provisional system comprises:
a step of providing the handling member having the contact surface;
a step of providing the primary substrate over which the at least one electronic device is arranged, which has a functional surface;
a step of temporarily securing the handling member with said at least one electronic device, via the plurality of first interaction molecules and the plurality of second interaction molecules, said first and second interaction molecules (5, 7) interacting with each other by reversible chemical interaction.

13. The handling method according to claim 11, wherein the chemical and/or physical treatment for breaking the chemical interaction between the plurality of first interaction molecules and the plurality of second interaction molecules comprises the emission of a light radiation at a first wavelength.

14. The handling method according to claim 13, wherein the light radiation at the first wavelength is emitted by the handling member, or throughout the handling member.

15. The handling method according to claim 13, wherein said at least one electronic device is an optoelectronic device capable of emitting a light radiation at the first wavelength when supplied with electrical energy, the separation step being implemented by supplying the electronic device with electrical energy.

16. The handling method according to claim 11, comprising a transfer phase implemented after the phase of providing a provisional system, the transfer phase comprising:
a step of detaching said at least one electronic device off the primary substrate, in particular by mechanical tension applied to the body of the handling member; and
a positioning step in which the contact surface of the handling member is positioned opposite a receiving surface of a secondary substrate.

17. The handling method according to claim 15, wherein the primary substrate comprises a plurality of electronic devices distributed over an emitting surface of the primary substrate, said emitting surface comprising electronic connections configured to allow powering each electronic device of the plurality of electronic devices individually in a power supply step (E91).

18. The handling method according to claim 17, wherein the electrical energy supply step (E91) is selectively implemented on at least one electronic device of the plurality of electronic devices.

19. The handling method according to claim 11, comprising a step of functionalizing the contact surface of the handling member implemented before the phase of providing a provisional system, wherein the contact surface is functionalized so as to enable the first interaction molecules to be bonded to the contact surface.

20. The handling method according to claim 11, comprising a step of functionalizing the functional surface of the electronic device implemented before the phase of providing a provisional system, in which the functional surface is functionalized so as to enable the second interaction molecules to be bonded to the functional surface.

21. The handling method according to claim 11, comprising an activation step, wherein at least one amongst the contact surface and the functional surface is subjected to a physical or chemical activation treatment so as to activate reactive chemical groups on the plurality of first interaction molecules and/or on the plurality of second interaction molecules.

22. The handling method according to claim 12 and according to any one of claims 13 to 21, wherein the temporary securing step is implemented by a reversible chemical reaction between the plurality of first interaction molecules and the plurality of second interaction molecules.

23. The handling method according to claim 12 and according to any one of claims 13 to 22, wherein the temporary securing step is implemented by a Diels-Alder reaction between the plurality of first molecules interaction and the plurality of second interaction molecules.

24. The handling method according to claim 12 and according to any one of claims 13 to 23, wherein the temporary securing step is performed by a click chemistry reaction between the plurality of first interaction molecules and the plurality of second interaction molecules.

25. The handling method according to claim 11, wherein the first interaction molecules and/or the second interaction molecules comprise at least one carbon chain.

26. The handling method of claim 25, wherein the at least one carbon chain has a distal end at the level of which a distal active site is arranged configured to enable the reversible chemical interaction between the first interaction molecules and the second interaction molecules.

27. The handling method of claim 26, wherein the at least one carbon chain has a proximal end at the level of which a proximal active site is arranged configured to enable the at least one chain carbon to be bonded to the functional surface or to the contact surface.
